(19) United States
(12) Patent Application Publication
(10) Pub. No.: US 2023/0116828 A1
(43) Pub. Date: Apr. 13, 2023

(54) HAND-HELD AUTOMOTIVE INDUCTIVE HEATING UNIT

(71) Applicant: Norco Industries, Inc., Compton, CA (US)

(72) Inventor: Frank Casale, Compton, CA (US)

(73) Assignee: Norco Industries, Inc., Compton, CA (US)

(21) Appl. No.: 17/496,609

(22) Filed: Oct. 7, 2021

(51) Int. Cl. H05B 6/10; H05K 1/18; H05B 6/06; H05B 6/04; H05B 6/42

(52) U.S. Cl. CPC H05B 6/101; H05K 1/18; H05B 6/06; H05B 6/04; H05B 6/42; H05K 2201/1003

(57) ABSTRACT

A hand-held heating unit is disclosed having a turbine connected to a generator to generate electrical power from a compressed air source. The electrical power produced by the generator is suppled to a transformer to establish a voltage which is in turn used to energize a coil with an alternating current. The current causes a magnetic field to form in the coil that can be used to heat ferrous materials within the coil. A circuit board can control the current and frequency for different applications.

### BACKGROUND

The present invention relates to hand-held heating units used in the automotive industry, and more particularly to a hand held heating unit that uses a source of compressed air to generate electrical power for inductive heating.

Acetylene torches are commonly used in automotive service applications where high intensity heat is needed. These devices produce heat by burning acetylene gas. By adding oxygen gas, these torches can produce flame temperatures of 5,620° F. and can be used to cut, heat, weld, and braze various metals. The basic torch consists of two high-pressure cylinders (one apiece for oxygen and acetylene) and two corresponding pressure regulators. A dualine hose transfers oxygen and acetylene from the regulators to the torch handle.

When working on a vehicle's engine, for example, there are situations where it is not optimal to have an open flame such as that used in the acetylene torch. First, the flame heats surrounding elements such as seals, gaskets, and cables that are not designed to withstand such temperatures. Also, there may be situations where flammable materials such as fuel is stored nearby. In such cases, a more focused heating device is needed.

Induction heaters have replaced acetylene torches in situations where an open flame is not desirable. An example of an induction heater is found in U.S. Pat. No. 6,563,096, the content of which is incorporated herein by reference. The heater uses electrical current from a current source such as a wall outlet to generate a magnetic field in a coil, which in turn generates heat to a ferrous target inside the coil. Such devices are especially well suited for loosening bolts on engine components that have for various reasons become stuck. Induction heaters confine the energy to the object within the coil, so there is no unnecessary or deleterious heating of nearby objects. There are also very portable and convenient, can be used when a vehicle component is removed from the vehicle or on the vehicle itself. While this device is useful for its intended purpose, it requires that the device be used proximal to a source of electricity. In certain situations, it may not be convenient to use the heater if there is not a nearby electrical outlet. There are no currently viable alternatives to an electrical power driven heat gun of this type. Moreover, the magnetic field has a frequency associated with it that affects the heating of the object. Most induction heaters are optimized for steel, making them less effective for other metals. There is currently no product that allows the frequency to be adjusted for different metals by controlling the frequency of the current that creates the magnetic field.

### SUMMARY OF THE INVENTION

The present invention is a hand-held inductive heating unit for use in automotive service applications and the like, that produces energy in the form of heat that is powered solely by a source of compressed air. The present invention employs inductive heating system using a generator that converts kinetic energy from a rotating fan blade into electrical current. The fan blade is rotated by the compressed air, which is typically prevalent in automotive service stations. The compressed air (via a hose or canister) rotates the fan blade that is attached to a shaft to rotate the shaft at a high rate of speed. The spinning shaft is connected to an electrical generator to produce an electrical current, which is passed through a coil to form a magnetic field in the coil. Ferrous objects within the coil in the magnetic field draws energy from the field in the form of heat, the magnitude of which depends on the material being heated. The present invention can preferably be held in a user's hand with a handle and trigger to actuate the inductive heating process. This heat energy can be applied to various objects such as loosening nuts and bolts that previously required torches or heaters that used electrical power.

The handheld unit of the present invention can be used anywhere in a variety of places that lack immediate on demand AC current. In addition to the compressed air turning the generator, the exhaust air exiting the fan can be diverted to also act as a cooling mechanism if needed. The invention has the advantage of the ability to adjust the frequency of the current in order to work on different metals. This is a significant improvement over existing heaters that operate at a single frequency by resonating a tuned circuit with the workpiece. That is, the electronics of existing induction heaters are tuned to operate within a very tight frequency range that are designed for metals that heat efficiently within that range, e.g. steel. However, aluminum alloys heat more efficiently when excited at different frequencies due to differences in the physical characteristics between the metals. Unlike current tools that are ill-suited for applications involving aluminum, the present invention can use multiple frequencies to support both steel, aluminum, and other metals, permitting the present invention to be used over a wider range of applications.

These and other advantages of the present invention will best be understood with reference to the Figures and the detailed description of the invention below.

### BRIEF DESCRIPTION OF THE DRAWINGS

FIG. 1 is an enlarged, elevated perspective view of the compressed air to electrical energy portion of the present invention; and

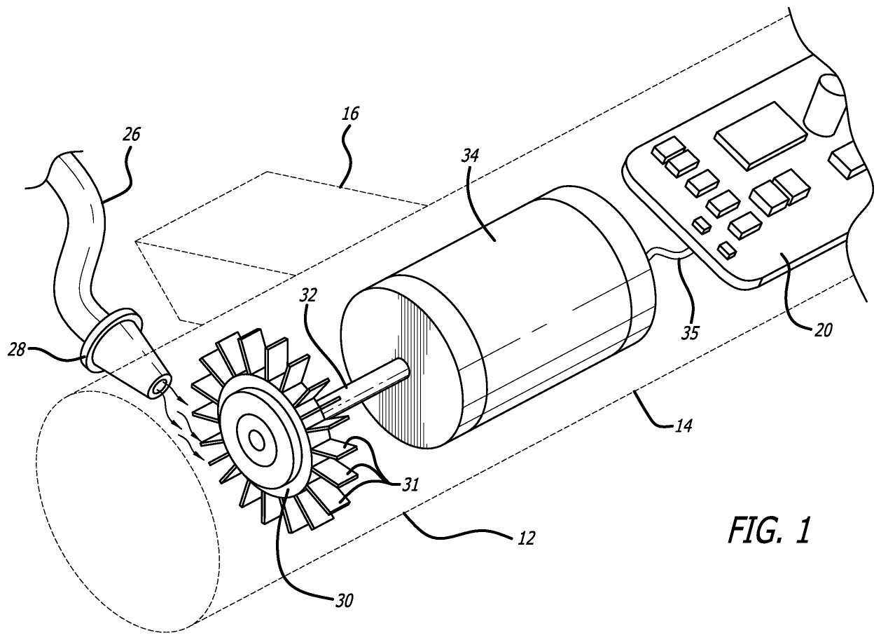

FIG. 2 is a schematic diagram of the present invention.

### DETAILED DESCRIPTION OF THE PREFERRED EMBODIMENTS

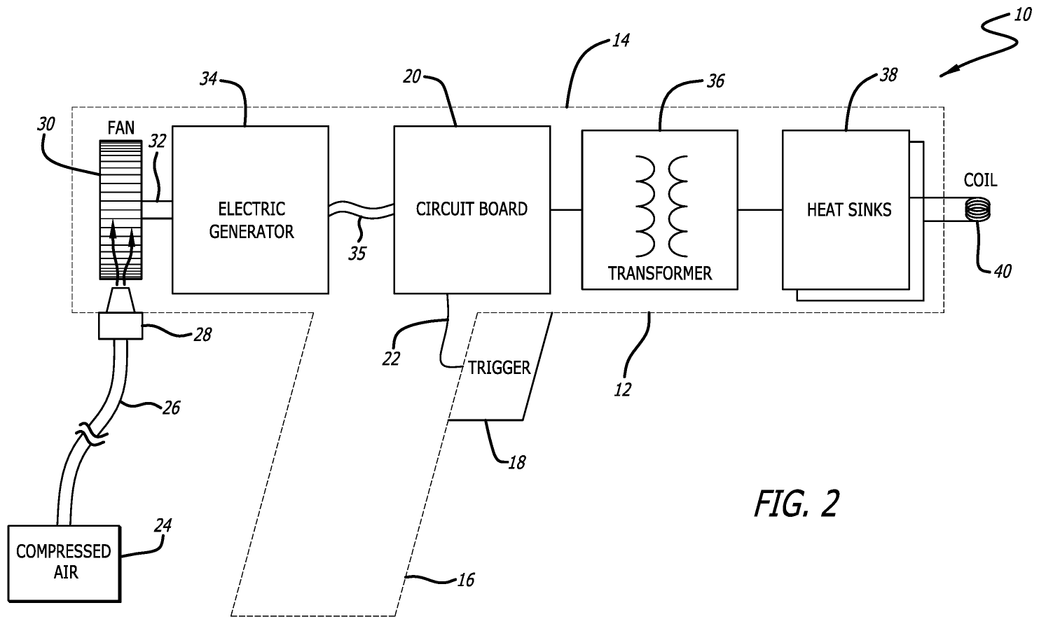

The present invention is a device for generating focused heat using one or more sources of energy, at least one of those sources being a supply of compressed air. In one preferred embodiment, alternate sources of energy can be compressed air and a battery, compressed air and electrical current, or a combination of all three power sources. FIG. 2 is a schematic of a device 10 for generating focused heat within a coil 40 using a magnetic field produced by electrical current passing through the coil 40. The device 10 includes a housing 12 having a body portion 14 and a handle portion 16. In a preferred embodiment, the body portion 14 has a length that is less than or equal to thirty centimeters (30 cm), making it both handheld and portable. In the embodiment depicted, the handle portion 16 is formed with a trigger 18 or other actuator but in other embodiments the handle and body can approximate more of a cylindrical configuration. The trigger 18 is connected to a switch (not shown) that in turn is connected to a circuit board 20 in the body portion 14 of the housing 12. Actuating the trigger 18 closes the switch and completes a circuit, a portion of which is formed by wire 22, to actuate the device 10. Other mechanisms could be used in place of a trigger 18, such as a switch, dial, sliding button, press button, and the like to actuate the device.

The device 10 is connected to a source of compressed air 24, which may be a compressor, a canister, or a pump. The source of compressed air 24 is connected either directly or via an air hose 26 to an air inlet port/nozzle 28 to direct and accelerate the airflow through the inlet. The nozzle forces the rapidly moving air over a turbine or fan 30, which is preferably formed with blades or vanes 31 to improve the efficiency of the rotation of the fan 30. The fan 30 includes a shaft 32 which in turn is connected to an electrical generator 34. Rotation of the shaft 32 as the fan spins is converted by the electrical generator 34 into electrical power, and the current is used to power the circuit board 20 in the housing 12.

The circuit board 20 interprets the electrical power from the electrical generator 34 via cable 35 and uses the current to energize the transformer 36 in the housing 12. The transformer can be used to establish a desired alternating current based on the settings that are stored in the circuit board 20. The frequency of the alternating current developed in the transformer can be adjusted to either steel, aluminum, or another frequency range depending upon the application and job to be performed. A dial, switch, or other control on the housing can be used to select the appropriate frequency (and hence heating condition) based on the specific application.

There are two ways to control the heat using the processor. The first way is to employ a duty cycle to cycle the circuit on and off according to a predetermined pattern. Another way to manage the amount of heat generated is to adjust the frequency of the alternating current, which in turn can vary the energy being generated and thus the heat produced. The voltage established in the transformer 36 is used to pass an alternating current in the coil 40, which in turn generates a magnetic field inside the coil. Ferrous materials inside the coil absorb energy from the magnetic field and are heated up thereby. To moderate the amount of heat generated, a heat sink typically in the form of a pair of parallel plates 38 are placed proximal the coil 40 to absorb some of the excess heat produced by the AC current.

Exhaust air in the housing 12 can be vented through the handle 16 or another port on the housing 12 to perform a cooling function. The cool air uses convection to remove heat from an object or surface heated by the device 10.

While certain preferred embodiments have been described and depicted herein and in the drawings, it is understood that the invention is not limited to those depictions and descriptions unless specifically so expressed. Rather, a person of ordinary skill in the art will readily appreciate certain modifications, substitutions, and variations and the invention is intended to include all such modifications, substitutions, and variations. Accordingly, the scope of the claims are properly determined by the appended claims using their customary and ordinary meanings, consistent with but not limited by the descriptions and depictions herein.

I claim:

1. A hand-held inductive heating unit, comprising:
a housing including an air pressure inlet port;
a fan disposed in the housing and configured to rotate a shaft in response to a flow of air entering the air pressure inlet port;
a generator in the housing and cooperating with the fan to produce electrical power from the rotation of the turbine's shaft;
a circuit board in the housing and configured to modulate the electrical power;
a transformer in the housing configured to adjust a voltage or current derived from the electrical power;
a heat sink in the housing and having the voltage applied thereto; and
a working coil connected to the transformer for passing an alternating current therein to establish a magnetic field in the coil.

2. The hand-held inductive heating unit of claim 1, wherein the heat sink is a pair of metal plates.

3. The hand-held inductive heating unit of claim 1, further comprising a trigger connected to the housing for actuating the unit.

4. The hand-held inductive heating unit of claim 3, wherein the trigger forms part of an electrical circuit that closes when the trigger is actuated.

5. The hand-held inductive heating unit of claim 1, wherein the housing has a length of no greater than thirty centimeters.

6. The hand-held indicative heating unit of claim 1, further comprising a nozzle to accelerate the air entering the air pressure inlet port.

7. The hand-held inductive heating unit of claim 1, wherein an exhaust air flow exiting the turbine can be directed to cool an object heated by the unit.

8. The hand-held inductive unit of claim 1, further comprising a non-stationary source of compressed air connected to the housing.

9. The hand-held inductive unit of claim 1, further comprising a stationary source of compressed air connected to the housing.

10. The hand-held inductive unit of claim 1, wherein the circuit board controls the electrical power to resonate at a user selected frequency from first and second frequencies.

11. The hand-held inductive unit of claim 10, wherein the first frequency is optimized to heat steel.

12. The hand-held inductive unit of claim 10, wherein the second frequency is optimized to heat aluminum.

13. The hand-held inductive unit of claim 10, wherein the circuit board uses a duty cycle to turn the unit on and off according to a pattern to control an amount of heat generated by the unit.
